(19) United States
(12) Patent Application Publication
(10) Pub. No.: US 2025/0105811 A1
(43) Pub. Date: Mar. 27, 2025

(54) REGULATED MOS-BASED LOAD FOR STABILIZATION OF HF AMPLIFIER/MIXER GAIN VS. PVT

(71) Applicant: Apple Inc., Cupertino, CA (US)

(72) Inventors: Milad Darvishi, San Diego, CA (US); Hongrui Wang, San Jose, CA (US); Abbas Komijani, Mountain View, CA (US)

(21) Appl. No.: 18/662,354

(22) Filed: May 13, 2024

Related U.S. Application Data
(60) Provisional application No. 63/584,776, filed on Sep. 22, 2023.

(51) Int. Cl. H03G 3/30; H03F 3/19

(52) U.S. Cl. CPC H03G 3/3036; H03F 3/19; H03G 2201/103; H03G 2201/307

(57) ABSTRACT

Systems and methods are provided for using a metal oxide semiconductor based (MOS-based) resistor bank as a load of an amplifier/mixer to adjust the gain of the amplifier/mixer across PVT variations. The gain is adjusted by regulating the impedance of the MOS-based resistor bank to emulate a desirable resistance change over temperature across all PTV variations. The voltage adding on the gate of the MOS-based resistor bank is controlled so that the resistance of the MOS-based resistor bank is a desired value and follow a predetermined variation across the PVT variations.

### CROSS-REFERENCE TO RELATED APPLICATIONS

This application claims priority to U.S. Provisional Application No. 63/584,776 filed Sep. 22, 2023, entitled “REGULATED MOS-BASED LOAD STABILIZATION OF HF AMPLIFIER/MIXER GAIN VS. PVT,” which is incorporated by reference in its entirety herein.

### BACKGROUND

The present disclosure relates generally to radio frequency front end (RFFE) circuitry, and more specifically to process, voltage, and temperature (PVT) variation effects on RFFE components.

In an electronic device, the RFFE circuitry (e.g., including a transmitter and a receiver) may be coupled to one or more antennas to enable the electronic device to both transmit and receive wireless signals. The RFFE circuitry may adjust one or more signals before transmission or after reception by the one or more antennas. Indeed, one or more amplifiers/mixers of the RFFE circuitry may contribute to the adjustment. Gains of the amplifiers/mixers may deviate across PVT variations, which may affect a signal to noise distortion ratio (SNDR). As such, it may be desired that gains associated with the amplifiers/mixers are regulated across PVT variations to improve the SNDR.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, gain adjustment circuitry may include a first transistor and a first amplifier, having a first input coupled to a source of the first transistor and a first current source. The gain adjustment circuitry may include a second transistor having a gate coupled to an output of the first amplifier and a gate of the first transistor. The gain adjustment circuitry may also include a resistance coupled to a second input of the first amplifier, and the resistance may be coupled to a second current source.

In another embodiment, a transceiver may include a filter and circuitry coupled to the filter. The filter may include a first amplifier, a second amplifier, and a first transistor coupled to a first current source at a first input of the first amplifier, and the first current source is configured to provide a first current. The filter may include a second transistor coupled to an output of the first amplifier and the first transistor, and the second transistor is coupled to a second amplifier. The filter may also include a resistance coupled to a second input of the first amplifier, and the resistance is coupled to a second current source configured to provide a second current based on a process variation, a voltage variation, or a temperature variation of the second transistor.

In yet another embodiment, a method may include receiving a characteristic parameter associated with a process, a voltage, or a temperature of a first transistor coupled to a first amplifier, and the first transistor is coupled to a second transistor and an output of a second amplifier, and the second transistor is coupled to a first current source at a first input of the second amplifier, and a resistance is coupled to a second input of the second amplifier and a second current source that is configured to provide a second current. The method may also include adjusting the second current source to provide the second current based on the characteristic parameter.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings described below in which like numerals refer to like parts.

FIG. 1 is a block diagram of an electronic device, according to embodiments of the present disclosure;

FIG. 2 is a functional diagram of the electronic device of FIG. 1, according to embodiments of the present disclosure;

FIG. 3 is a schematic diagram of a transmitter of the electronic device of FIG. 1, according to embodiments of the present disclosure;

FIG. 4 is a schematic diagram of a receiver of the electronic device of FIG. 1, according to embodiments of the present disclosure;

FIG. 5 is a schematic view of an embodiment of a gain adjustment circuit of the transmitter of FIG. 3 and/or the receiver of FIG. 4, according to embodiments of the present disclosure;

FIG. 6 includes a plot showing a change of a current with respect to temperature and a plot showing a corresponding change of a resistance of a metal oxide semiconductor (MOS) transistor with respect to temperature for the gain adjustment circuit of FIG. 5, according to embodiments of the present disclosure;

FIG. 7 includes a schematic view of a second embodiment of a gain adjustment circuit of the transmitter of FIG. 3 and/or the receiver of FIG. 4 having a process-tracking device, a plot showing a change of a current with respect to temperature and a plot showing a corresponding change of a resistance of a MOS transistor with respect to temperature, according to embodiments of the present disclosure;

FIG. 8 is a schematic view of a third embodiment of a gain adjustment circuit of the transmitter of FIG. 3 and/or the receiver of FIG. 4 having multiple transistors in a process-tracking device and multiple transistors in a feedback loop of an amplifier, according to embodiments of the present disclosure;

FIG. 9 is a schematic view of a fourth embodiment of a gain adjustment circuit of the transmitter of FIG. 3 and/or the receiver of FIG. 4 having a voltage detector and a protection circuit, according to embodiments of the present disclosure;

FIG. 10 is a schematic view of a fifth embodiment of a gain adjustment circuit of the transmitter of FIG. 3 and/or the receiver of FIG. 4 using a power supply, according to embodiments of the present disclosure; and

FIG. 11 is a flowchart of a method for manipulating a current source in a gain adjustment circuit of the transmitter of FIG. 3 and/or the receiver of FIG. 4, according to embodiments of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately,” “near,” “about,” “close to,” “similar” and/or “substantially” should be understood to mean including close to a target (e.g., design, value, amount), such as within a margin of any suitable or contemplatable error (e.g., within 0.1% of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on. Additionally, the term “set” may include one or more. That is, a set may include a unitary set of one member, but the set may also include a set of multiple members.

Gains of amplifiers/mixers may deviate across process, voltage, and temperature (PVT) variations, which may affect signal to noise distortion ratio (SNDR). As such, it may be beneficial to design a circuit (e.g., a gain adjustment circuit) so that the gain associated with an amplifier/mixer may be adjusted and controlled across the PVT variations to improve the SNDR. The disclosure embodiments provide a metal oxide semiconductor-based (MOS-based) resistor bank as a load of an amplifier/mixer to adjust the gain of an amplifier/mixer (e.g., of a transceiver) across the PVT variations. Regulating the impedance of the MOS-based resistor bank may adjust the gain to emulate a desirable resistance variation across all PTV variations. Adjusting voltage on a gate terminal of the MOS-based resistor bank may adjust resistance of the MOS-based resistor bank to a desired value and follow a predetermined variation across all PTV variations, as described in greater detail herein.

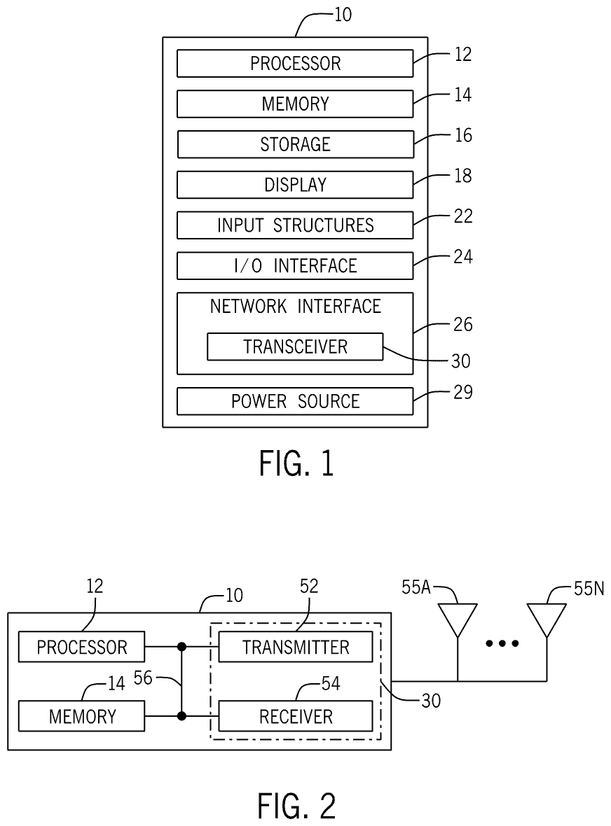

FIG. 1 is a block diagram of an electronic device 10, according to embodiments of the present disclosure. The electronic device 10 may include, among other things, one or more processors 12 (collectively referred to herein as a single processor for convenience, which may be implemented in any suitable form of processing circuitry), memory 14, nonvolatile storage 16, a display 18, input structures 22, an input/output (I/O) interface 24, a network interface 26, and a power source 29. The various functional blocks shown in FIG. 1 may include hardware elements (including circuitry), software elements (including machine-executable instructions) or a combination of both hardware and software elements (which may be referred to as logic). The processor 12, memory 14, the nonvolatile storage 16, the display 18, the input structures 22, the input/output (I/O) interface 24, the network interface 26, and/or the power source 29 may each be communicatively coupled directly or indirectly (e.g., through or via another component, a communication bus, a network) to one another to transmit and/or receive signals between one another. It should be noted that FIG. 1 is merely one example of a particular implementation and is intended to illustrate the types of components that may be present in the electronic device 10.

By way of example, the electronic device 10 may include any suitable computing device, including a desktop or notebook computer, a portable electronic or handheld electronic device such as a wireless electronic device or smartphone, a tablet, a wearable electronic device, and other similar devices. In additional or alternative embodiments, the electronic device 10 may include an access point, such as a base station, a router (e.g., a wireless or Wi-Fi router), a hub, a switch, and so on. It should be noted that the processor 12 and other related items in FIG. 1 may be embodied wholly or in part as software, hardware, or both. Furthermore, the processor 12 and other related items in FIG. 1 may be a single contained processing module or may be incorporated wholly or partially within any of the other elements within the electronic device 10. The processor 12 may be implemented with any combination of general-purpose microprocessors, microcontrollers, digital signal processors (DSPs), field programmable gate array (FPGAs), programmable logic devices (PLDs), controllers, state machines, gated logic, discrete hardware components, dedicated hardware finite state machines, or any other suitable entities that may perform calculations or other manipulations of information. The processors 12 may include one or more application processors, one or more baseband processors, or both, and perform the various functions described herein.

In the electronic device 10 of FIG. 1, the processor 12 may be operably coupled with a memory 14 and a nonvolatile storage 16 to perform various algorithms. Such programs or instructions executed by the processor 12 may be stored in any suitable article of manufacture that includes one or more tangible, computer-readable media. The tangible, computer-readable media may include the memory 14 and/or the nonvolatile storage 16, individually or collectively, to store the instructions or routines. The memory 14 and the nonvolatile storage 16 may include any suitable articles of manufacture for storing data and executable instructions, such as random-access memory, read-only memory, rewritable flash memory, hard drives, and optical discs. In addition, programs (e.g., an operating system) encoded on such a computer program product may also include instructions that may be executed by the processor 12 to enable the electronic device 10 to provide various functionalities.

In certain embodiments, the display 18 may facilitate users to view images generated on the electronic device 10. In some embodiments, the display 18 may include a touch screen, which may facilitate user interaction with a user interface of the electronic device 10. Furthermore, it should be appreciated that, in some embodiments, the display 18 may include one or more liquid crystal displays (LCDs), light-emitting diode (LED) displays, organic light-emitting diode (OLED) displays, active-matrix organic light-emitting diode (AMOLED) displays, or some combination of these and/or other display technologies.

The input structures 22 of the electronic device 10 may enable a user to interact with the electronic device 10 (e.g., pressing a button to increase or decrease a volume level). The I/O interface 24 may enable electronic device 10 to interface with various other electronic devices, as may the network interface 26. In some embodiments, the I/O interface 24 may include an I/O port for a hardwired connection for charging and/or content manipulation using a standard connector and protocol, such as the Lightning connector, a universal serial bus (USB), or other similar connector and protocol. The network interface 26 may include, for example, one or more interfaces for a personal area network (PAN), such as an ultra-wideband (UWB) or a BLUETOOTH® network, a local area network (LAN) or wireless local area network (WLAN), such as a network employing one of the IEEE 802.11x family of protocols (e.g., WI-FI®), and/or a wide area network (WAN), such as any standards related to the Third Generation Partnership Project (3GPP), including, for example, a 3rd generation (3G) cellular network, universal mobile telecommunication system (UMTS), 4th generation (4G) cellular network, Long Term Evolution® (LTE) cellular network, Long Term Evolution License Assisted Access (LTE-LAA) cellular network, 5th generation (5G) cellular network, and/or New Radio (NR) cellular network, a 6th generation (6G) or greater than 6G cellular network, a satellite network, a non-terrestrial network, and so on. In particular, the network interface 26 may include, for example, one or more interfaces for using a cellular communication standard of the 5G specifications that include the millimeter wave (mmWave) frequency range (e.g., 24.25-300 gigahertz (GHz)) that defines and/or enables frequency ranges used for wireless communication. The network interface 26 of the electronic device 10 may allow communication over the aforementioned networks (e.g., 5G, Wi-Fi, LTE-LAA, and so forth).

The network interface 26 may also include one or more interfaces for, for example, broadband fixed wireless access networks (e.g., WIMAX®), mobile broadband Wireless networks (mobile WIMAX®), asynchronous digital subscriber lines (e.g., ADSL, VDSL), digital video broadcasting-terrestrial (DVB-T®) network and its extension DVB Handheld (DVB-H®) network, ultra-wideband (UWB) network, alternating current (AC) power lines, and so forth.

As illustrated, the network interface 26 may include a transceiver 30. In some embodiments, all or portions of the transceiver 30 may be disposed within the processor 12. The transceiver 30 may support transmission and receipt of various wireless signals via one or more antennas, and thus may include a transmitter and a receiver. Gains of amplifiers/mixers of the transceiver 30 may deviate across process, voltage, and temperature (PVT) variations, which may affect signal to noise distortion ratio (SNDR). Accordingly, it may be beneficial to adjust the gain associated with the amplifiers/mixers across the PVT variations to improve the SNDR. For instance, a metal oxide semiconductor-based (MOS-based) resistor bank may be used as a load of an amplifier/mixer of the transceiver 30 to adjust the gain of the amplifier/mixer across the PVT variations. Regulating the impedance of the MOS-based resistor bank may adjust the gain to emulate a desirable resistance variation across all PTV variations. Adjusting voltage on a gate terminal of the MOS-based resistor bank may adjust resistance of the MOS-based resistor bank to a desired value and follow a predetermined variation across all PTV variations. The power source 29 of the electronic device 10 may include any suitable source of power, such as a rechargeable lithium polymer (Li-poly) battery and/or an alternating current (AC) power converter.

FIG. 2 is a functional diagram of the electronic device 10 of FIG. 1, according to embodiments of the present disclosure. As illustrated, the processor 12, the memory 14, the transceiver 30, a transmitter 52, a receiver 54, and/or antennas 55 (illustrated as 55A-55N, collectively referred to as an antenna 55) may be communicatively coupled directly or indirectly (e.g., through or via another component, a communication bus, a network) to one another to transmit and/or receive signals between one another.

The electronic device 10 may include the transmitter 52 and/or the receiver 54 that respectively enable transmission and reception of signals between the electronic device 10 and an external device via, for example, a network (e.g., including base stations or access points) or a direct connection. As illustrated, the transmitter 52 and the receiver 54 may be combined into the transceiver 30. The electronic device 10 may also have one or more antennas 55A-55N electrically coupled to the transceiver 30. The antennas 55A-55N may be configured in an omnidirectional or directional configuration, in a single-beam, dual-beam, or multi-beam arrangement, and so on. Each antenna 55 may be associated with one or more beams and various configurations. In some embodiments, multiple antennas of the antennas 55A-55N of an antenna group or module may be communicatively coupled to a respective transceiver 30 and each emit radio frequency signals that may constructively and/or destructively combine to form a beam. The electronic device 10 may include multiple transmitters, multiple receivers, multiple transceivers, and/or multiple antennas as suitable for various communication standards. In some embodiments, the transmitter 52 and the receiver 54 may transmit and receive information via other wired or wireline systems or means.

As illustrated, the various components of the electronic device 10 may be coupled together by a bus system 56. The bus system 56 may include a data bus, for example, as well as a power bus, a control signal bus, and a status signal bus, in addition to the data bus. The components of the electronic device 10 may be coupled together or accept or provide inputs to each other using some other mechanism.

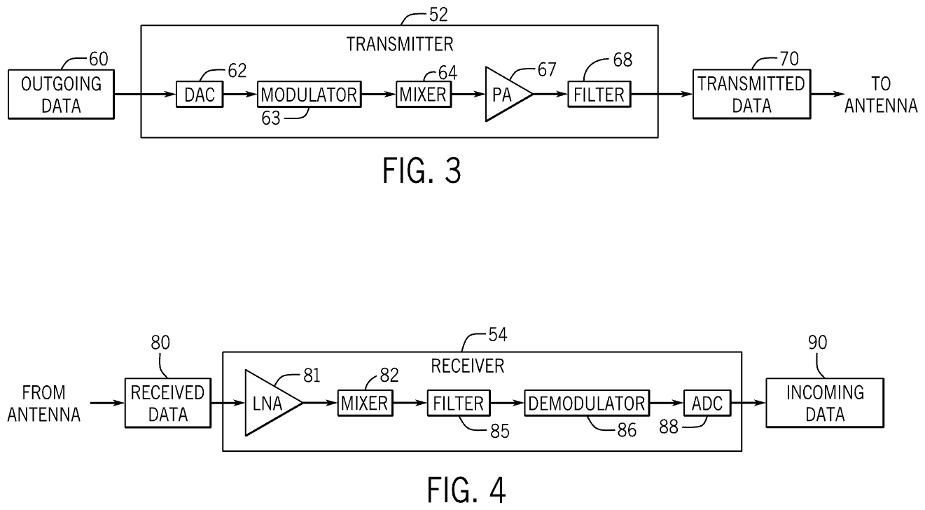

As mentioned above, the transceiver 30 of the electronic device 10 may include a transmitter and a receiver that are coupled to at least one antenna to enable the electronic device 10 to transmit and receive wireless signals. FIG. 3 is a block diagram of a transmitter 52 (e.g., transmit circuitry) that may be part of the transceiver 30, according to embodiments of the present disclosure. As illustrated, the transmitter 52 may receive outgoing data 60 in the form of a digital signal to be transmitted via the one or more antennas 55. A digital-to-analog converter (DAC) 62 of the transmitter 52 may convert the digital signal to an analog signal, and a modulator 63 may combine the converted analog signal with a carrier signal. A mixer 64 may be used to combine the carrier signal with other signals (e.g., a local oscillator signal from a local oscillator) to generate a radio frequency signal. A power amplifier (PA) 67 receives the radio frequency signal from the mixer 64, and may amplify the radio frequency signal to a suitable level to drive transmission of the signal via the one or more antennas 55. A filter 68 (e.g., filter circuitry and/or software) of the transmitter 52 may then remove undesirable noise from the amplified signal to generate transmitted data 70 to be transmitted via the one or more antennas 55. The filter 68 may include any suitable filter or filters to remove the undesirable noise from the amplified signal, such as a bandpass filter, a bandstop filter, a low pass filter, a high pass filter, and/or a decimation filter. The power amplifier 67 and/or the filter 68 may be referred to as part of a radio frequency front end (RFFE), and more specifically, a transmit front end (TXFE) of the electronic device 10. Additionally, the transmitter 52 may include any suitable additional components not shown, or may not include certain of the illustrated components, such that the transmitter 52 may transmit the outgoing data 60 via the one or more antennas 55. For example, the transmitter 52 may include an additional mixer and/or a digital up converter (e.g., for converting an input signal from a baseband frequency to an intermediate frequency). As another example, the transmitter 52 may not include the filter 68 if the power amplifier 67 outputs the amplified signal in or approximately in a desired frequency range (such that filtering of the amplified signal may be unnecessary).

FIG. 4 is a schematic diagram of a receiver 54 (e.g., receive circuitry) that may be part of the transceiver 30, according to embodiments of the present disclosure. As illustrated, the receiver 54 may receive received data 80 from the one or more antennas 55 in the form of an analog signal. A low noise amplifier (LNA) 81 may amplify the received analog signal to a suitable level for the receiver 54 to process. A mixer 82 may combine the amplified signal with other signals (e.g., a local oscillator signal from a local oscillator) to generate an intermediate or baseband frequency signal. A filter 85 (e.g., filter circuitry and/or software) may remove undesired noise from the signal, such as cross-channel interference. The filter 85 may also remove additional signals received by the one or more antennas 55 that are at frequencies other than the desired signal. The filter 85 may include any suitable filter or filters to remove the undesired noise or signals from the received signal, such as a bandpass filter, a bandstop filter, a low pass filter, a high pass filter, and/or a decimation filter. The low noise amplifier 81 and/or the filter 84 may be referred to as part of the RFFE, and more specifically, a receiver front end (RXFE) of the electronic device 10. A demodulator 86 may remove a radio frequency envelope and/or extract a demodulated signal from the filtered signal for processing. An analog-to-digital converter (ADC) 88 may receive the demodulated analog signal and convert the signal to a digital signal of incoming data 90 to be further processed by the electronic device 10. Additionally, the receiver 54 may include any suitable additional components not shown, or may not include certain of the illustrated components, such that the receiver 54 may receive the received data 80 via the one or more antennas 55. For example, the receiver 54 may include an additional mixer and/or a digital down converter (e.g., for converting an input signal from an intermediate frequency to a baseband frequency).

As discussed above, multiple amplifiers (e.g., the PA 67, the LNA 81) and/or mixers (e.g., the mixer 64, the mixer 82) may be included in the device 10. The gain of the amplifiers/mixers may vary across process, voltage, and temperature (PVT) variations. For example, the variations of the gain may be process dependent, chip-to-chip dependent, or temperature dependent. To improve the signal to noise distortion ratio (SNDR), it may be desirable to adjust the gain of an amplifier/mixer across PVT variations. The disclosure embodiments provide a metal oxide semiconductor-based (MOS-based) resistor bank as a load of an amplifier/mixer to adjust the gain of an amplifier/mixer (e.g., of a transceiver) across the PVT variations. Regulating the impedance of the MOS-based resistor bank may adjust the gain to emulate a desirable resistance variation across all PTV variations. Adjusting voltage on a gate terminal of the MOS-based resistor bank may adjust resistance of the MOS-based resistor bank to a desired value and follow a predetermined variation across all PTV variations, as described in greater detail herein.

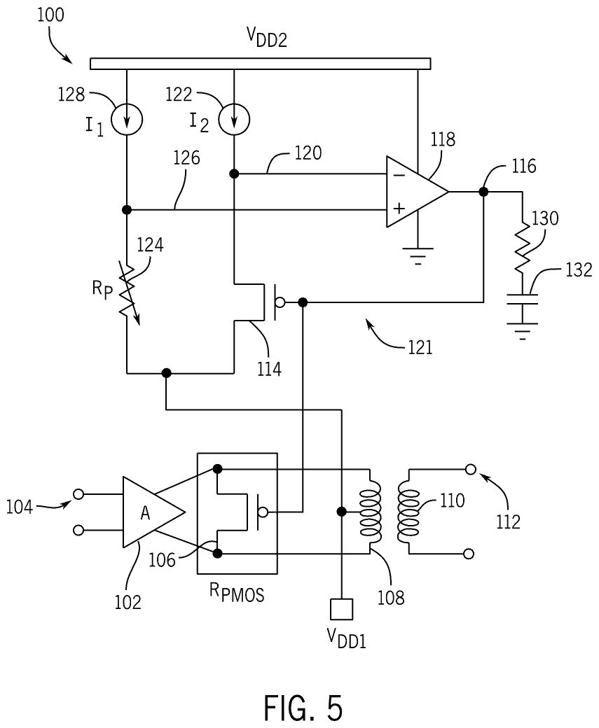

FIG. 5 is a schematic view of an embodiment of a gain adjustment circuit 100 that may adjust the gain of an amplifier/mixer (e.g., the PA 67, the LNA 81, the mixer 64, the mixer 82, and so on). An amplifier 102 may have an input (e.g., input terminals) 104, and a p-channel metal oxide semiconductor (PMOS) transistor 106 may be coupled to the amplifier 102 (e.g., at supply terminals) as a load. Source and drain terminals of the PMOS transistor 106 may be coupled to a first terminal of an inductor 108, which may be magnetically or inductively coupled to an inductor 110 of an output 112 of the gain adjustment circuit 100 in operation. A power supply V_{DD1} may be coupled to a second terminal of the inductor 108. A gate terminal of the PMOS transistor 106 and a gate terminal of a replica PMOS transistor 114 may be coupled to a common node 116, which may be coupled to an output of an operational amplifier (op amp) 118 (e.g., an operational transconductance amplifier (OTA)). The replica PMOS transistor 114 may have similar properties (e.g., electrical properties, property variations cross PVT) as the PMOS transistor 106, and voltages connected to drain and source terminals of the replica PMOS transistor 114 may have the same or similar values as those voltages connected to the drain and source terminals of the PMOS transistor 106. Accordingly, resistance of the replica PMOS transistor 114 may have an identical or similar value as the resistance Rₚₘₒₛ of the PMOS transistor 106 and may also have identical or similar variations cross PVT. Thus, the resistance of the replica PMOS transistor 114 may be a replica of the resistance Rₚₘₒₛ of the PMOS transistor 106. The source terminal of the replica

PMOS transistor 114 may be coupled to a negative input 120 of the op amp 118 so that the replica PMOS transistor 114 may be included in a feedback loop 121 to the negative input 120 of the op amp 118. The source terminal of the replica PMOS transistor 114 may also be coupled to a current source 122, which provides a current I₂. A switched-resistor bank 124 having a resistance of Rₚ may be coupled, at a first terminal, to a positive input 126 of the op amp 118 and a current source 128, which provides a current I₁. The switched-resistor bank 124 may be calibrated and the resistance Rₚ may be kept constant by trimming (e.g., calibrated by using an external resistor in Automatic Test Equipment (ATE)) so that its value is predetermined. The switched-resistor bank 124 may also be coupled, at a second terminal, to the drain of the replica PMOS transistor 114. In the gain adjustment circuit 100, a power supply V_{DD2} may provide power for the op amp 118, the current source 122, and the current source 128. A voltage value of V_{DD2} may be larger than a voltage value of V_{DD1}, and the voltage values may provide sufficient headroom for the manipulating of the currents I₁ and/or I₂. In the gain adjustment circuit 100, an output of the op amp 118 may be coupled to a resistor 130 and a capacitor 132. Although, PMOS transistors are used in the embodiment illustrated in FIG. 5, n-channel metal oxide semiconductor (NMOS) transistors may be used in the gain adjustment circuit 100 in certain embodiments. In addition, more than one transistors (e.g., a series/parallel combination of MOS transistors) may be used for the load of the amplifier 102, and more than one transistors (e.g., a series/parallel combination of MOS transistors) may be used in the feedback loop 121 to the negative input 120 of the op amp 118. Moreover, to obtain improved matching between the replica PMOS transistor 114 and the PMOS transistor 106, the two transistors 114, 106 may be displaced in a vicinity (e.g., within a threshold distance) of each other.

As illustrated in the gain adjustment circuit 100, the resistance of the replica PMOS transistor 114 may have the identical or similar value as the resistance Rₚₘₒₛ of the PMOS transistor 106. The output of the OP 118 may have nonzero values when there is a difference between voltage at the negative input 120 and voltage at the positive input 126. Since the replica PMOS transistor 114 is in the feedback loop 121 to the negative input of the OP 118, when the output of the OP 118 is higher than a threshold voltage of the gate voltage of the replica PMOS transistor 114, the replica PMOS transistor 114 may be turned on and the current I₂ may flow through the replica PMOS transistor 114 until the voltages at the negative input 120 and the positive input 126 are equal. Accordingly, we may have a relationship between the resistances Rₚ and Rₚₘₒₛ, as described in Equation [1]:

$${I}_{1} \times {R}_{p} = {I}_{2} \times {R}_{pmos} \qquad [ 1 ]$$

Accordingly, the resistance Rₚₘₒₛ of the PMOS transistor 106 may be represented by a relationship described in Equation [2]:

$${R}_{pmos} = {R}_{p} \frac{{I}_{1}}{{I}_{2}} \qquad [ 2 ]$$

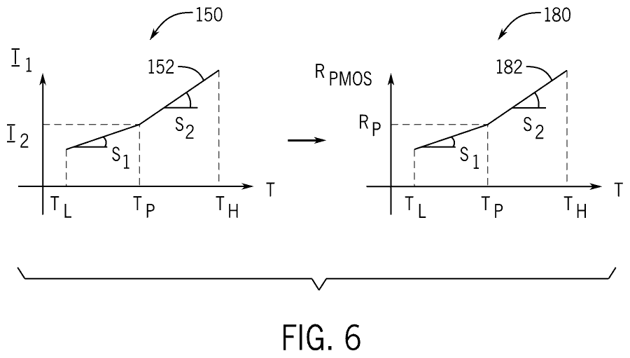

As such, a desirable variation of the resistance Rₚₘₒₛ across all PVT variations may be obtained by manipulating the current I₁ and/or the current I₂, as illustrated in FIG. 6 below. Thus a desirable variation of the gain of the amplifier 102 across all PVT variations may be obtained by adjusting the resistance Rₚₘₒₛ of the PMOS transistor 106. Accordingly, the SNDR of the amplifier 102 across all PVT variations may be improved by regulating the gain of the amplifier 102. The values of the current I₁ and/or the current I₂ may be determined to reduce or minimize the mismatch between them. In addition, a product of the current I₁ and the resistance Rₚ may be increased or optimized to reduce the sensitivity to the offset of the OP 118.

In FIG. 6, a plot 150 shows a change of the current I₁ with respect to temperature (T), and a plot 180 shows a corresponding change of the resistance Rₚₘₒₛ with respect to temperature according to the Equation [2] described above. In the plot 150, the current I₂ may have a constant value, and the current I₁ may change with respect to temperature along a curve 152. As illustrated in the plot 150, the curve 152 may include a dual-slope Proportional To Absolute Temperature (PTAT) current, which has two slopes (e.g., S₁ and S₂) along the temperature axis. On the curve 152, the current I₁ may have a minimum value at low temperature T_{L} and a maximum value at high temperature T_{H}, and the current I₁ may have a value of I₂ at a temperature T_{P} between the low temperature T_{L} and the high temperature T_{H}. According to Equation [2], the resistance Rₚₘₒₛ may change with respect to temperature along a curve 182 similar to the curve 152, as illustrated in the plot 180. In the plot 180, the curve 182 may also include a dual-slope PTAT current having the same two slopes (e.g., S₁ and S₂) along the temperature axis. On the curve 182, the resistance Rₚₘₒₛ may have a minimum value at low temperature T_{L} and a maximum value at high temperature T_{H}, and the resistance Rₚₘₒₛ may have the value of Rₚ at the temperature T_{P} when the current I₁ has the value of I₂. It should be noted that, although only variations across temperature is considered in the embodiments illustrated in FIG. 6, variations across all PVT variations may be considered in other embodiments (e.g., the resistance Rₚₘₒₛ may be regulated to change with respect to voltage and process). It should also be noted that, although a dual-slope relationship is used for the curve 152 and 182 in the embodiments illustrated in FIG. 6, other relationships (e.g., linear, nonlinear) may be used in other embodiments.

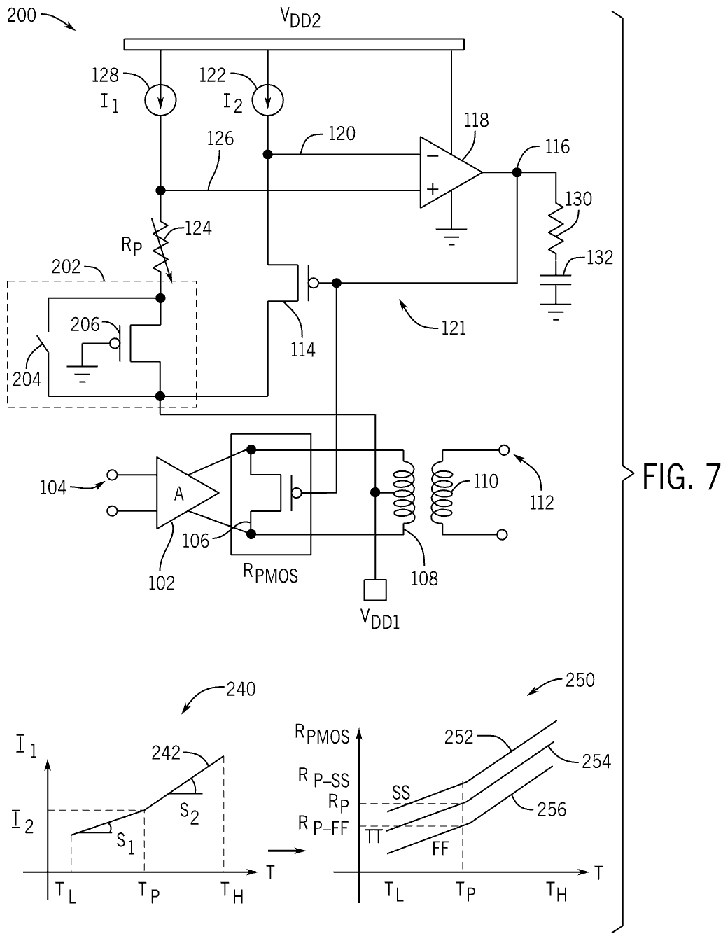

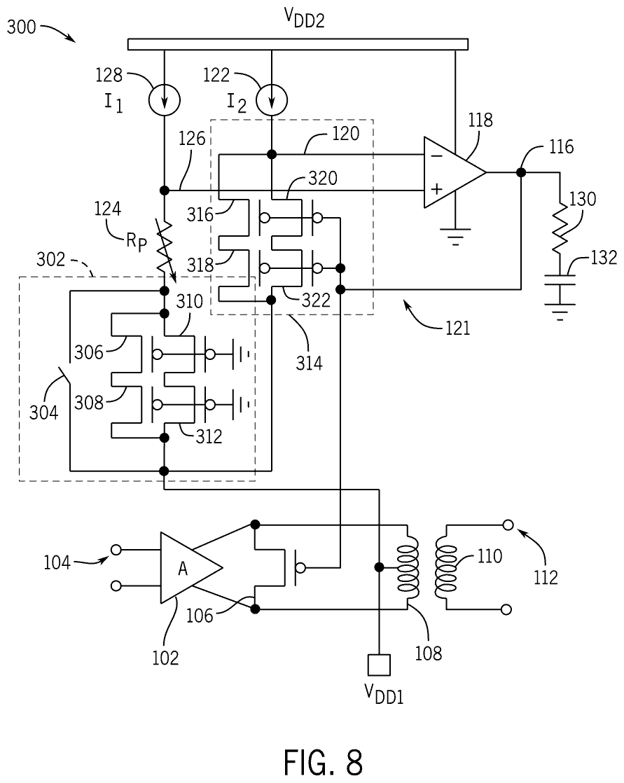

FIG. 7 shows another embodiment of a gain adjustment circuit 200 having a process-tracking device 202 that may adjust the gain of an amplifier/mixer (e.g., the PA 67, the LNA 81, the mixer 64, the mixer 82, and so on). FIG. 7 also includes a plot 240 shows a change of the current I₁ with respect to temperature (T) and a plot 250 shows a corresponding change of the resistance Rₚₘₒₛ with respect to temperature according to the Equation [2] described above. In the gain adjustment circuit 200, the process-tracking device 202 may be configured to selectively track a process variation by using a switch 204 (e.g., turning off the switch 204 to enable and turning on the switch 204 to disable). Adding the process-tracking device 202 to the positive input 126 of the op amp 118 may modify a relationship between the resistances Rₚ and Rₚₘₒₛ. For example, the process-tracking device 202 may use a PMOS transistor 206 to modify the relationship between the resistances Rₚ and Rₚₘₒₛ, as illustrated in the plot 250. In the plot 240, the current I₂ may have a constant value, and the current I₁ may change with respect to temperature along a curve 242. As illustrated in the plot 240, the curve 242 may include a dual-slope PTAT current, which has two slopes (e.g., S₁ and S₂) along the temperature axis. On the curve 242, the current I₁ may have a minimum value at low temperature T_{L} and a maximum value at high temperature T_{H}, and the current I₁ may have a value of I₂ at a temperature T_{P} between the low temperature T_{L} and the high temperature T_{H}. According to Equation [2], the resistance Rₚₘₒₛ may change with respect to temperature similarly as the curve 242, as illustrated in the plot 250. In the plot 250, the resistance Rₚₘₒₛ may change with respect to temperature (T) along a curve 252 with an embodiment (e.g., slow-slow (SS) process corner) of the process-tracking device 202, along a curve 254 with another embodiment (e.g., typical-typical (TT) process corner) of the process-tracking device 202, and along a curve 256 with a different embodiment (e.g., fast-fast (FF) process corner) of the process-tracking device 202. In the plot 250, the curves 252, 254, and 256 may also include a dual-slope PTAT having the same two slopes (e.g., S₁ and S₂) along the temperature axis. As illustrated in the plot 250, when the current I₁ has the value of I₂, the resistance Rₚₘₒₛ may have the value of Rₚ at the temperature T_{P} on the curve 254, the value of R_{p-SS} on the curve 252 and the value of R_{p-TT} on the curve 256. Accordingly, by using the process-tracking device 202 in the gain adjustment circuit 200, the relationship between the resistances Rₚ and Rₚₘₒₛ may be modified. Although, PMOS transistors are used in the embodiment illustrated in FIG. 7, NMOS transistors may be used in the gain adjustment circuit 200 in certain embodiments. In addition, more than one transistors (e.g., a series/parallel combination of MOS transistors) may be used in the process-tracking device 202, and more than one transistors (e.g., a series/parallel combination of MOS transistors) may be used in the feedback loop 121 to the negative input of the op amp 118, as illustrated in FIG. 8. It should be noted that, although only variations across temperature is considered in the embodiments illustrated in FIG. 7, variations across all PVT variations may be considered in other embodiments (e.g., the resistance Rₚₘₒₛ may be regulated to change with respect to voltage and process).

FIG. 8 shows another embodiment of a gain adjustment circuit 300 having a voltage detector (e.g., a V_{DD1} detector) 402 that may adjust the gain of an amplifier/mixer (e.g., the PA 67, the LNA 81, the mixer 64, the mixer 82, and so on). In the gain adjustment circuit 300, a process-tracking device 302 may be configured to selectively track a process variation by using a switch 304 (e.g., turning off the switch 304 to enable and turning on the switch 304 to disable). Adding the process-tracking device 302 to the positive input 126 of the op amp 118 may modify the relationship between the resistances Rₚ and Rₚₘₒₛ. For example, the process-tracking device 302 may use multiple PMOS transistors (e.g., PMOS transistor 306, PMOS transistor 308, PMOS transistor 310, and PMOS transistor 312) to modify the relationship between the resistances Rₚ and Rₚₘₒₛ. In addition, more than one PMOS transistors (e.g., PMOS transistor 316, PMOS transistor 318, PMOS transistor 320, and PMOS transistor 322) may be used in a transistor group 314 of the feedback loop 121 to couple the negative input of the op amp 118. Although, PMOS transistors are used in the embodiment illustrated in FIG. 8, NMOS transistors may be used in the gain adjustment circuit 300 in certain embodiments. In addition, different numbers of transistors (e.g., n x m transistors, where n and m may be any suitable integers) may be used in the process-tracking device 302, and different numbers of transistors (e.g., n x m transistors, where n and m may be any suitable integers) may be used in the transistor group 314 of the feedback loop 121 to the negative input of the op amp 118.

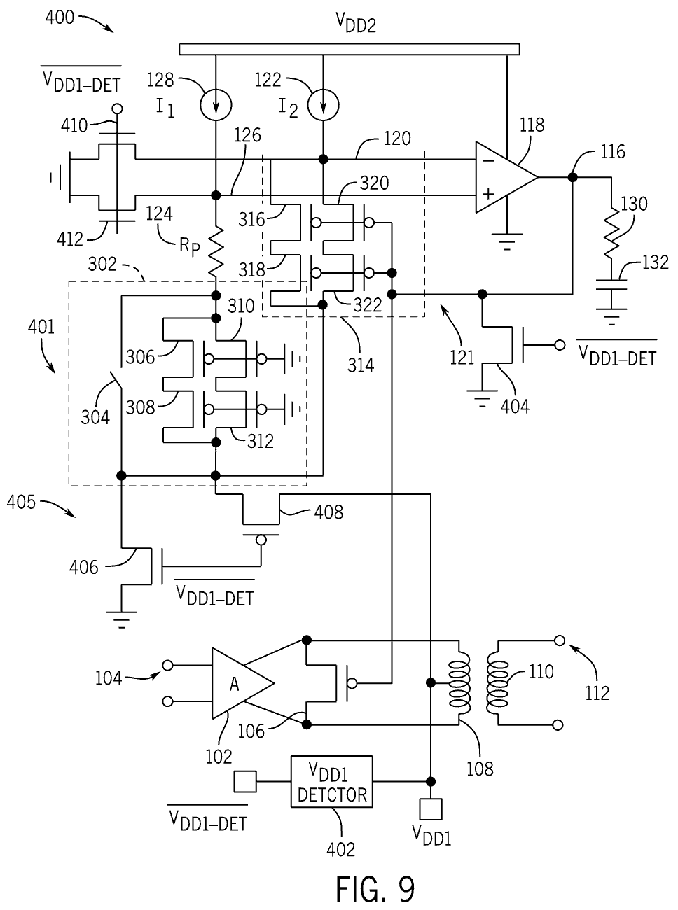

Generally, V_{DD2} may increase to a higher voltage value before V_{DD1}, and a protection circuit may protect the transmitter 52, the receiver 54, and/or a gain adjustment circuit of the transmitter 52 or the receiver 54 (e.g., core devices having transistors with close-to-minimum channel-length) by detecting the real-time V_{DD1} value and managing voltage differences between respective gate, drain, and source terminals of some transistors (e.g., keeping the voltage differences smaller than a predetermined value (e.g., <<1 volt)). FIG. 9 shows an embodiment of a gain adjustment circuit 400 with a protection circuit 401. The V_{DD1} detector 402 may detect a value of the V_{DD1} and output an absolute value of the detected value, V̅_̅{̅D̅D̅1̅-̅d̅e̅t̅}̅. The value V̅_̅{̅D̅D̅1̅-̅d̅e̅t̅}̅ may be used to provide the real-time V_{DD1} value. Various types of transistors may be used in the protection circuit 401. For example, an NMOS transistor 404 may be used at the output of the op amp 118. A source terminal of the NMOS transistor 404 may be coupled to the common node 116, a voltage of value V̅_̅{̅D̅D̅1̅-̅d̅e̅t̅}̅ may be provided at a gate terminal of the NMOS transistor 404, and a drain terminal of the NMOS transistor 404 may be coupled to a ground. In addition, a CMOS transistor 405 may be used in the protection circuit 401. For example, the CMOS transistor 405 including an NMOS transistor 406 and a PMOS transistor 408 may be coupled between the process-tracking device 302 and the power supply V_{DD1}, and a voltage of value V̅_̅{̅D̅D̅1̅-̅d̅e̅t̅}̅ may be applied to the gate terminals of the NMOS transistor 406 and the PMOS transistor 408, as illustrated in FIG. 9. In addition, a pair of NMOS transistors, including an NMOS transistor 410 and an NMOS transistor 412, may be coupled between the current source 122 and the current source 128, and a voltage of value V̅_̅{̅D̅D̅1̅-̅d̅e̅t̅}̅ may be applied to the gate terminals of the pair of NMOS transistors 410, 412, as illustrated in FIG. 9.

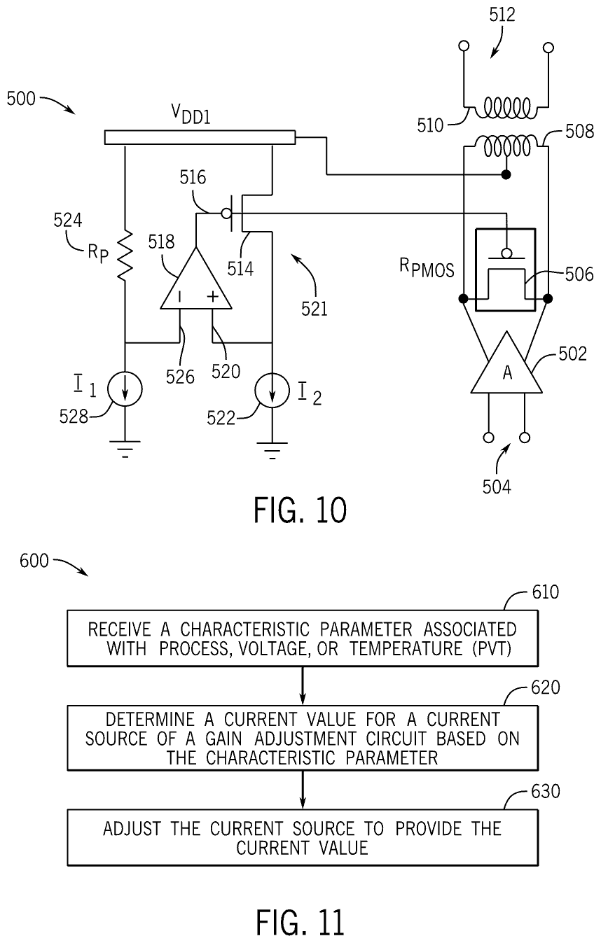

FIG. 10 is a schematic view of an embodiment of a gain adjustment circuit 500 that may adjust the gain of an amplifier/mixer (e.g., the PA 67, the LNA 81, the mixer 64, the mixer 82, and so on). An amplifier 502 may have an input 504, and a PMOS transistor 506 may be coupled to the amplifier 502 as a load. Source and drain terminals of the PMOS transistor 506 may be coupled to respective terminals of an inductor 508, which may be magnetically or inductively coupled to an inductor 510 of an output 512 of the amplifier 102. A power supply V_{DD1} may be tapped into or coupled to the inductor 508 (e.g., splitting the inductor 508 into two portions or halves). A gate terminal of the PMOS transistor 506 and a gate terminal of an NMOS transistor 514 may be coupled to a common node 516, which may be coupled to an output of an operational amplifier (op amp) 518 (e.g., an operational transconductance amplifier (OTA)). A source terminal of the NMOS transistor 514 may be coupled to the power supply V_{DD1}, and a drain terminal of the NMOS transistor 514 may be coupled to a positive input terminal 520 of the op amp 518 so that the NMOS transistor 514 may be included in a feedback loop 521 to the positive input terminal 520 of the op amp 518. The drain terminal of the replica PMOS transistor 114 may also be coupled to a current source 522, which provides a current I₂. A switched-resistor bank 524 having a resistance of Rₚ may be coupled to a negative input terminal 526 of the op amp 118 and a current source 528, which provides a current I₁. The switched-resistor bank 524 may be calibrated and the resistance Rₚ may be kept constant by trimming so that its value is predetermined. The switched-resistor bank 524 may also be coupled to the power supply V_{DD1}. In the embodiment illustrated in FIG. 10, although only a single transistor 506 is used for the load of the amplifier 502 and only a single transistor 506 is used in the feedback loop 521 to the positive input terminal of the op amp 518, in other embodiments, more than one transistors (e.g., a series/parallel combination of MOS transistors) may be used for the load of the amplifier 502 and more than one transistors (e.g., a series/parallel combination of MOS transistors) may be used in the feedback loop 521 to the positive input terminal 520 of the op amp 518. A protection circuit may be reduced/avoided for the gain adjustment circuit 500, since only one power supply, the power supply V_{DD1}, is used in the gain adjustment circuit 500. Similar as in the gain adjustment circuit 200 and the gain adjustment circuit 300, the gain adjustment circuit 500 may also include a process-tracking device (e.g., 202, 302) to track a process variation.

FIG. 11 is a flowchart of a method 600 for manipulating a current source in a gain adjustment circuit. At block 610, the device 10 may receive an operating characteristic parameter (e.g., a process variation value, a voltage variation value, a temperature variation value) associated with PVT variations. For example, the device 10 may receive the operating characteristic parameter via a voltage detector, a power detector, a current sensor, a temperature sensor, or any other suitable sensor that may determine a value related to PVT variation. At block 620, after receiving the operating characteristic parameter, the processor 12 may determine a current value (e.g., I₁, I₂) for a current source (e.g., the current source 128, the current source 122) of a gain adjustment circuit (e.g., the gain adjustment circuit 100, the gain adjustment circuit 200, the gain adjustment circuit 300, the gain adjustment circuit 400, the gain adjustment circuit 500) based on the characteristic parameter. For example, the processor 12 may store (e.g., in the memory 14 and/or the storage 16) predetermined values for the current source corresponding different PVT variations or calculate or determine the current value based on a predetermined algorithm. At block 630, the processor 12 may adjust the current source to provide the current value to the gain adjustment circuit.

Technical effects of the present disclosure include reducing gain variation based on systems and methods described herein. Indeed, current mirror circuitry is described herein that involves one or more transistors operated in a triode region and one or more transistors operated in a saturation region. By doing so, gain variation may be reduced while maintaining permissible amounts of main current generation (e.g., tailored to the particular system).

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ,” it is intended that such elements are to be interpreted under 35 U.S.C. 112 (f). However, for any claims containing elements designated in any other manner, it is intended that such elements are not to be interpreted under 35 U.S.C. 112 (f).

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

1. Gain adjustment circuitry comprising:
a first transistor;
a first amplifier having a first input coupled to a source of the first transistor and a first current source;
a second transistor having a gate coupled to an output of the first amplifier and a gate of the first transistor; and
a resistance coupled to a second input of the first amplifier, the resistance being coupled to a second current source.

2. The gain adjustment circuitry of claim 1, wherein the first transistor and the second transistor comprise a same type of transistors.

3. The gain adjustment circuitry of claim 2, comprising a voltage detector configured to detect a voltage value of a power supply coupled to the first transistor and the second transistor, and a protection circuit configured to protect the gain adjustment circuitry based on the voltage value.

4. The gain adjustment circuitry of claim 3, wherein the protection circuit comprises one or more transistors configured to receive a voltage having the voltage value.

5. The gain adjustment circuitry of claim 1, wherein one of the first transistor and the second transistor comprises a p-channel metal oxide semiconductor transistor, and another of the first transistor and the second transistor comprises an n-channel metal oxide semiconductor transistor.

6. The gain adjustment circuitry of claim 1, wherein the second current source is configured to provide a second current based on a process variation, a voltage variation, or a temperature variation associated with the second transistor.

7. The gain adjustment circuitry of claim 6, wherein the second current changes linearly with respect to the process variation, the voltage variation, or the temperature variation associated with the second transistor.

8. The gain adjustment circuitry of claim 6, wherein the second current changes nonlinearly with respect to the process variation, the voltage variation, or the temperature variation associated with the second transistor.

9. The gain adjustment circuitry of claim 1, comprising a process-tracking device configured to selectively track a process variation.

10. A transceiver comprising:
a filter; and
circuitry coupled to the filter comprising
a first amplifier,
a second amplifier,
a first transistor coupled to a first current source at a first input of the first amplifier, the first current source being configured to provide a first current,
a second transistor coupled to an output of the first amplifier and the first transistor, the second transistor being coupled to the second amplifier, and
a resistance coupled to a second input of the first amplifier, the resistance being coupled to a second current source configured to provide a second current based on a process variation, a voltage variation, or a temperature variation of the second transistor.

11. The transceiver of claim 10, wherein a gain of the second amplifier varies corresponding to the process variation, the voltage variation, or the temperature variation of the second transistor.

12. The transceiver of claim 11, wherein a variation of the gain is associated with a signal to noise distortion ratio of the second amplifier.

13. The transceiver of claim 11, wherein the second current changes linearly with respect to the process variation, the voltage variation, or the temperature variation associated with the second transistor.

14. The transceiver of claim 11, wherein the second current changes nonlinearly with respect to the process variation, the voltage variation, or the temperature variation associated with the second transistor.

15. The transceiver of claim 10, wherein the first current has a constant value.

16. The transceiver of claim 10, wherein the first transistor and the second transistor comprise a same type of transistors.

17. The transceiver of claim 10, wherein the first transistor and the second transistor comprise different types of transistors.

18. A method comprising:
receiving a characteristic parameter associated with a process, a voltage, or a temperature of a first transistor coupled to a first amplifier, the first transistor being coupled to a second transistor and an output of a second amplifier, the second transistor being coupled to a first current source at a first input of the second amplifier, a resistance being coupled to a second input of the second amplifier and a second current source that is configured to provide a second current; and
adjusting the second current source to provide the second current based on the characteristic parameter.

19. The method of claim 18, comprising determining a value to adjust the second current source from a plurality of predetermined values based on the characteristic parameter.

20. The method of claim 18, comprising determining a value for the second current based on the characteristic parameter and a predetermined algorithm.
